(19) United States
(12) Patent Application Publication
(10) Pub. No.: US 2009/0129004 A1
(43) Pub. Date: May 21, 2009

(54) Electrically conducting and optically transparent nanowire networks

(75) Inventor: George Gruner, Los Angeles, CA (US)

Correspondence Address: VENABLE LLP, P.O. BOX 34385, WASHINGTON, DC, 20043-9998, US

(73) Assignee: Regents of the University of California, Oakland, CA (US)

(21) Appl. No.: 12/078,326

(22) Filed: Mar. 28, 2008

Related U.S. Application Data
(63) Continuation of application No. PCT/US2007/024115, filed on Nov. 19, 2007.
(60) Provisional application No. 60/859,493, filed on Nov. 17, 2006.

(51) Int. Cl. H05K 1/09; H05K 1/00; G06F 1/16; B05D 5/12; H01B 1/22

(52) U.S. Cl. 361/679.21; 174/250; 174/257; 174/254; 427/108; 427/540; 427/553; 252/514

(57) ABSTRACT

A network of nanowires has a plurality of interconnected nanowires. Each interconnected nanowire includes a metal in its composition. The network of nanowires is electrically conducting and substantially transparent to visible light. An electronic or electro-optic device has a network of nanowires. The network of nanowires has a plurality of interconnected nanowires, each interconnected nanowire including a metal in its composition. The network of nanowires is electrically conducting and substantially transparent to visible light. A metal-oxide nanowire has a metal oxide doped with a second metal in a composition thereof. The metal-oxide nanowire is electrically conducting and substantially transparent to visible light.

### CROSS-REFERENCE TO RELATED APPLICATION

This application claims priority to U.S. Provisional Application No. 60/859,493 filed Nov. 17, 2006, the entire contents of which are hereby incorporated by reference.

### BACKGROUND

1. Field of Invention

This application relates to electrically conducting and optically transparent networks of nanowires, devices made from the nanowires and methods of production.

2. Discussion of Related Art

The contents of all references, including articles, published patent applications and patents referred to anywhere in this specification are hereby incorporated by reference.

Various oxide materials have been used for applications where electrical conductivity and optical transparency in the visible range are required. The current choice of material for such applications is indium-tin-oxide, ITO, that provides optical transmission above 90% with a sheet resistance of less that 100 (Ohmcm)⁻¹. While developed to perfection, the material has nevertheless several deficiencies. The material is deposited at high temperature, making compatibility with some (like polymeric) substrates problematic. The difficulty in patterning, together with the sensitivity to acidic and basic environments limits the use in certain applications. Brittleness of the material is obviously an issue for any application for which flexibility is required, and when tailored for such applications the sheet resistance is significantly higher (for the same transmittance) than an ITO film on a rigid substrate such as glass.

Other oxide materials have also been used as transparent coatings and electrodes. As an example, ZnO doped with a variety of dopants has been used in thin films for in a variety of applications where a transparent and electrically conducting film is required. While a continuous ZnO film doped with Al and other metallic elements has appropriate transparency in the visible spectral range and sheet resistance (M. K. Jayaray et al Bull. Mat. Soc 25, 227 (2002), the material is brittle and thus is not appropriate for applications where mechanical flexibility is required.

Thin films of metals, such as silver are also used as a transparent electronic material. The dc conductivity of good metals such as silver is approximately 6×10⁵ (Ohmscm)⁻¹. The components (real and imaginary part) of the optical conductivity have also been evaluated in the visible spectral range (G. R. Parins et al Phys Rev B23, 6408 (1981), R. T. Beach and R. W. Christy Phys Rev B12, 5277 (1977) and references cited therein).

Using these as input and using standard expressions for the optical transparency of thin films of thickness d (M. Dressel and G. Gruner: Electrodynamics of Solids, Cambridge University Press 2002) the sheet resistance and optical transparency in the visible region of the electromagnetic spectrum can be evaluated for films with different thickness. As an example, for a thickness of 5 nm, the sheet resistance is 3 ohms (corresponding to a conductivity of (6×10⁵ Ohmscm)⁻¹ and an optical transparency at 550 nm wavelength is 90%.

For films where the thickness is significantly smaller that the wavelength of light, the reflectivity is small. There is a well established relation between the optical conductivity σ_{ac} and the optical transmission T

$$T = \frac{1}{{( 1 + \frac{2 π}{c} {σ}_{a c} d )}^{2}} \qquad \text{/} 1 \text{/}$$

(M. Dressel and G. Gruner: Electrodynamics of Solids, Cambridge University Press 2002), and this relation also describes the parameters quoted above.

Various other electrically conducting materials are also currently developed for plastic, flexible electronics. Most are conducting polymers, and composites, materials that ensure mechanical flexibility, together with electronic conduction. Carbon nanotubes have also been used to fabricate transparent and electrically conducting films (see PCT application PCT/2005/047315 assigned to the same assignee as the current application). While the materials have the required flexibility, they do not have the sheet resistance and transparency performance required for certain applications.

Consequently, currently there is no material that displays optical transparency and sheet resistance comparable to that of ITO on a rigid substrate, such as glass, having at the same time appropriate mechanical flexibility. There is thus a need for improved optically transparent electrical conductors and devices made therefrom.

### SUMMARY

Further objectives and advantages will become apparent from a consideration of the description, drawings, and examples.

A network of nanowires according to an embodiment of the current invention has a plurality of interconnected nanowires. Each interconnected nanowire includes a metal in its composition. The network of nanowires is electrically conducting and substantially transparent to visible light.

An electronic or electro-optic device according to an embodiment of the current invention has a network of nanowires. The network of nanowires has a plurality of interconnected nanowires, each interconnected nanowire including a metal in its composition. The network of nanowires is electrically conducting and substantially transparent to visible light.

A metal-oxide nanowire according to an embodiment of the current invention has a metal oxide doped with a second metal in a composition thereof. The metal-oxide nanowire is electrically conducting and substantially transparent to visible light.

A method of producing an electronic or electro-optic device includes dispersing a plurality of nanowires in a liquid solution, depositing at least a portion of the liquid solution to provide a network of nanowires on a substrate, and transferring the nanowires from the substrate to another substrate to form at least a portion of an electronic or electro-optic device. The nanowires comprise at least one of metal nanowires or metal-oxide nanowires doped with a second metal.

### BRIEF DESCRIPTION OF THE DRAWINGS

The invention is better understood by reading the following detailed description with reference to the accompanying figures in which:

FIGS. 1a-1c provides an illustrative example of a nanowire network according to an embodiment of the current invention and also contrasted to a thin film. FIG. 1a is the top view of an interconnected network above the percolation threshold, FIG. 1b is a cutaway view of the network along the dashed line indicated on FIG. 1a, and FIG. 1c is a continuous thin film with the same cross sectional area as the network indicated on FIG. 1b.

FIG. 2 shows the optical transparency versus the sheet resistance of a silver and ZnO nanowire network with parameters as described in the specification according to an embodiment of the current invention.

FIG. 3 provides scanning electron microscope images of an electrically conducting silver nanowire network on a substrate according to an embodiment of the current invention. The image on the right clearly shows that the network is transparent.

FIGS. 4a-4f provides a schematic illustration of producing a nanowire network according to an embodiment of the current invention. FIG. 4a is an illustration of a patterned PDMS stamp and nanowire films made by vacuum filtration. FIG. 4b shows conformal contact between a PDMS stamp and nanowire films on the filter. FIG. 4c shows that after the conformal contact, the PDMS stamp is removed from the filter. Patterns of nanowire films are transferred onto the PDMS stamp without any damage. FIG. 4d shows a PDMS stamp with patterned nanowire films and a flat receiving substrate. FIG. 4e shows conformal contact between a PDMS stamp and the substrate. FIG. 4f shows that after removing the PDMS stamp from the substrate, all patterned nanotube films on the stamp are fully transferred onto the substrate.

FIG. 5 is an illustration of the top view of two interpenetrated nano-structure networks according to an embodiment of the current invention.

FIG. 6 shows a multilayer structure that incorporates a substrate, a nanowire network and an encapsulation layer according to an embodiment of the current invention.

FIG. 7 is a schematic illustration of a multilayer structure that includes a substrate, a “functional layer”, and a nano-structure or multiple nano-structure network.

FIG. 8 is a schematic illustration of an architecture that incorporates a substrate, a nanowire network, a “functional component” such as a chemical or nano-structured material and an encapsulation layer according to an embodiment of the current invention. Such a structure can alleviate the problem of easy removal of or damage to the “functional material” by encapsulating the (nanotube+functional material) with a layer.

FIG. 9 is a schematic illustration of an architecture for a supercapacitor using structured Ag nanowire Electrodes according to an embodiment of the current invention. Both the substrate and the electrolyte can be a polymer electrolyte for an entire solid state device. The Ag nanowire electrodes can be completely embedded in the electrolyte.

FIG. 10 shows a cyclovoltammogramm of a silver nanowire network supercapacitor as illustrated in FIG. 9.

FIG. 11 is a schematic illustration of a solar cell that has a nanowire network according to an embodiment of the current invention.

FIG. 12 is a schematic illustration of a light emitting diode that has a nanowire network according to an embodiment of the current invention.

FIG. 13 is a schematic illustration of a battery that has a nanowire network according to an embodiment of the current invention.

### DETAILED DESCRIPTION

In describing embodiments of the present invention illustrated in the drawings, specific terminology is employed for the sake of clarity. However, the invention is not intended to be limited to the specific terminology so selected. It is to be understood that each specific element includes all technical equivalents which operate in a similar manner to accomplish a similar purpose.

Some embodiments of the current invention are directed to a random network of transparent oxide and/or metal nanowires. An example of transparent oxide nanowires according to some embodiments of the current invention include, but are not limited to, doped ZnO. An example of metal nanowires according to some embodiments of the current invention includes, but is not limited to, silver (Ag) nanowires. A random network, while retaining the high conductivity and optical transparency also has mechanical flexibility. In addition, the one dimensional nature of the nanowires leads to increased optical transparency compared to a continuous, three dimensional material such as a film.

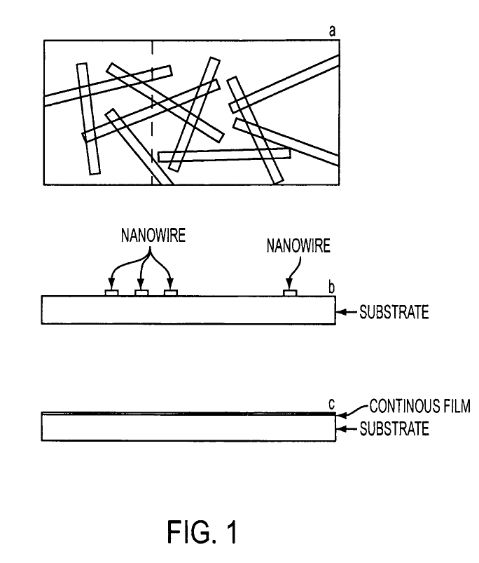

A random assembly of nanowires on a substrate can also be viewed as a new electronic material that offers several fundamental advantages for flexible electronics applications. These are derived from the architecture itself, from the attributes of the constituent wires, from the ease of fabrication, and compatibility with other materials such as polymers. The material's architecture is illustrated schematically in FIG. 1. With components that are conductors or semiconductors, such a two dimensional (2D) nanowire network is a conducting medium with several attractive attributes. 1. Electrical conductance. This value proposition assumes that the conductivity of the wires is large; the larger the nanowire conductivity, the better the network conductance. 2. Optical transparency. With ZnO, a transparent material, high optical transparency is also achieved even for a continuous film. However, high transparency is expected for other electrically conducting nanowires as well. A network of highly one-dimensional wires has high transparency, approaching 100%, for truly one-dimensional wires with aspect ratio approaching infinity. This is in contrast to networks formed of nanoparticles, for example, where substantial coverage of the surface—and thus small optical transparency—is needed for electrical conduction. 3. Flexibility. A random network of wires has, as a rule, significantly higher mechanical flexibility that a film, making the architecture eminently suited in particular for flexibility-requiring applications. 4. Fault tolerance. Breaking a conducting path leaves many others open, and the pathways for current flow will be rearranged. The concept, called fault tolerance, is used in many areas, from internet networks to networks of power lines. The same concept applies here as well.

### 1. Modeling of the Electrical and Optical Properties of Ag Nanowire Networks.

As a feature of the present invention, the nanowires that form the networks have diameters of less than 100 nm and aspect ratios of at least 10. The relationship between conductivity, sheet conductance and optical transparency is as follows.

The nanowire density of the nanowire network on a surface can be described by either:
average network thickness, d
nanotube surface density, sd or nanotube coverage c of the surface that supports the network

100% coverage of a network leads to an average thickness equivalent to the diameter of the nanowires, this also corresponds to a surface density of 100%. Networks with more or less that 100% coverage can be fabricated and are included within the scope of the current invention.

The dc, direct current conductivity σ_{dc} is a parameter that is independent of the nanowire density. The sheet conductance, the technically important parameter, is given by σ_{dc} d. Various factors determine the dc conductivity:

number of charge carriers (electrons or holes)

number of nanowire-nanowire interconnects per unit area

nanowire-nanowire interconnect resistance

Forming nanowires and assuming that the electrical and optical properties of the individual wires are the same as that of a continuous film leads to the following estimate for the sheet resistance and optical transmission of a nanowire network. An illustrative example of an interconnected network of nanowires is shown on FIG. 1. First one notes that a network made of a 50 nm×50 nm nanowires that covers, say 10% of the surface leads to the same optical absorption as that of a continuous film of 5 nm, i.e. 90%, due to the fact that the absorption is determined by the number of Ag atoms per unit area in the structure. If the nanowire network is grained so that the network, in a surface area determined by the length scale of the light, (typically 550 nm, a characteristic wavelength in the visible spectral range) contains a large number of nanowires the reflectivity will also be close to the reflectivity of a continuous film that has the same thickness as the average thickness of the nanowire network. Thus the optical transparency of the network of 50 nm×50 nm wires that cover 10% of the surface has the same transparency as a 5 nm thick continuous film. Given the fact that the dc conductivity is given by

$$σ = \frac{1}{R} \frac{l}{A} \qquad \text{/} 2 \text{/}$$

where R is the measured resistance, l is the length and A is the cross section, is inversely proportional to the cross sectional surface area of the conducting structure, the dc conductivity of the network is also the same as the continuous 5 nm thick film if the electrical conductivities of a film and a network are the same—assuming that the conductivities of a film and nanowires are the same.

The sheet resistance Rs—the resistance of a square shaped film—is given by

$$1 / Rs = \frac{1}{Rd} \qquad \text{/} 3 \text{/}$$

where d is the thickness of a film—or the average thickness of the network.

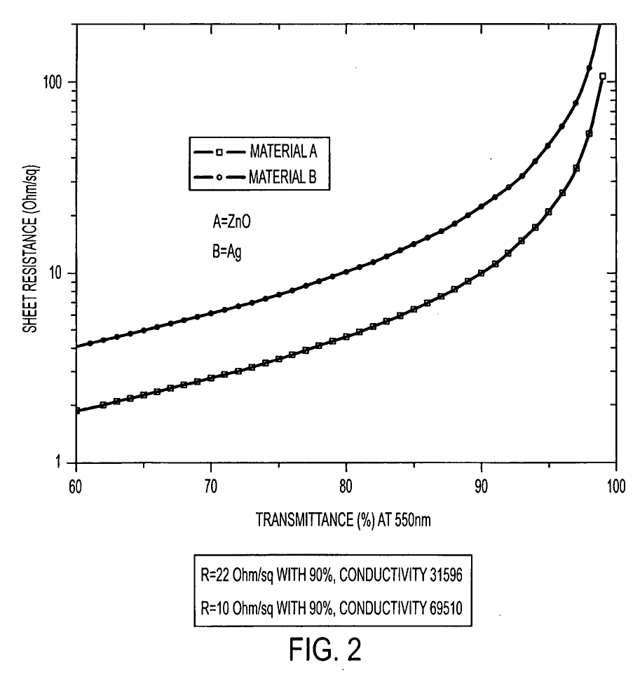

The electrical conductivity of silver nanowires is (0.8×10⁵ Ohmcm)⁻¹ (Y. Sun et al Chem. Mater. 14, 4736 (2002), 7.5 times smaller than the conductivity of a silver film, reflecting effects such as surface scattering. The optical conductivity is not affected by these factors and is the same or close to that of films of silver. Consequently, an interconnected network of nanowires is expected to have an optical transmission of 90% of the sheet resistance Rs of 3×6/0.8=21.2 Ohms. Equation /1/ above can then be used to establish a sheet resistance to optical transparency relation for Ag nanowire networks at different densities. This is shown on FIG. 2, using R=21 Ohms and T=90% as input parameters, by the dashed line incorporating the diamond symbols. The estimates given in the text and displayed on FIG. 2 are in agreement with recent calculations involving silver metal gratings (M. Kang et al Adv. Mat 19, 1301 (2007)).

The data in FIG. 1 demonstrates that a random network of Ag nanowires can be used as a transparent electronic material.

For randomly arranged nanowires an additional factor plays a role, further reducing the optical absorption and enhancing the transmission T. Only the component of the light polarized along the direction of the wires is effective. The absorbed power of electromagnetic radiation W, the loss, is simply given by

W=1/3Vσ₁E² /2/

where V is the volume occupied by the collection of nanowires, σ₁, is the real part of the optical conductivity, the factor 1/3 coming from the random orientations with respect to the applied electric field E₀. (The above expression is valid in the limit when the skin depth is larger that the cross section of the nanowire, an obviously satisfied condition for nanowires less than 100 nm thickness.) This effect will reduce the optical absorption and consequently increase the optical transparency, further improving the useful parameters for the material as a transparent electrical conductor. The dashed line incorporating the diamond symbols is expression /1/normalized to T=90% and Rs=21.2 Ohms.

### 2. Modeling of ZnO Networks

The parameters of ZnO films can be modeled using the parameters for continuous films. A typical 5000 A film has a resistivity of 5×10⁻⁴ Ohms cm and optical transparency of 90% (M. K. Jayaray et al bull Mat. Sci. 25, 227 (2002), H. Kim et al Appl. Phys. Lett 76, 259 (2000). This leads to a resistance of 10 Ohms for a network with an overall thickness of 5000 A. The argument advanced above leads therefore to a sheet resistance-optical transmission relation similar to for the Ag films described above. This is also displayed on FIG. 2 with the dashed lines incorporating the solid squares. derived by assuming that ZnO nanowires have the same resistance as a ZnO film.

The data in FIG. 2 demonstrates that a random network of ZnO nanowires can be used as a transparent electronic material.

### 2. Formation of Ag Nanowire Networks

Silver nanowires can be prepared using various preparation routes (E. A. Hernandez et al Nanotech 2004 Vol 3 Ch4 p156, A. Graff et al Eur. Phys. J. D. 34, 263 (2006) Y. Gao et al J. Phys. D. Appl. Phys. 38, 1061 (2005) (Y. Sun et al Chem. Mater., 14 (11), 4736-4745, 2002)). Such wires are typically 50-100 nm wide and can have a length exceeding one micron. Such wires are also commercially available.

There are several ways a silver nanowire network can be formed. Nanowire deposition methods may include drop casting, spin coating, roll-to-roll coating and transfer printing. In all cases, nanowires are dissolved in an aqueous liquid. The liquid can be water, alcohol, aromatic solvent or hydrocarbon.

Nanowires are prepared with PVP (polyvinyl pyrrolidone, povidone, polyvidone) wrapped around the nanowires (Y. Sun et al Chem. Mater., 14 (11), 4736-4745, 2002). PVP is soluble in water and other polar solvents. In water it has the useful property of Newtonian viscosity. In solution, it has excellent wetting properties and readily forms films. This makes it also an excellent coating or an additive to coatings. The polymer, wrapped around the nanowires hampers the propagation of electric charges from nanowire to nanowire, leading to a large resistance of the network. Consequently it has to be removed. This can be accomplished by heat treatment. The thermal gravimetry (TG) curve shows a two-step weight decline pattern with the inflexion points at ≈200 and 475° C. The first change corresponds to the removal of the PVP that attached to the Ag nanowires. (Y. Sun et al Chem. Mater., 14 (11), 4736-4745, 2002). Consequently, a heat treatment at this temperature leads to the removal of PVP and to a nanowire network with high electrical conductivity—approaching the conductivity, for a certain optical transparency that is given in FIG. 2.

### 3. Transfer Printing Method of Forming Nanowire Networks

A fabrication method that preserves the exceptional properties of nanowires has been developed. It yields consistently reproducible nanowire films and allows large-scale industrial production. This method combines a PDMS (poly-dimethysiloxane) based transfer-printing technique (N. P. Armitage, J-C P Gabriel and G. Grüner, “Langmuir-Blodgett nanotube films”, J. Appl. Phys. 95, 3228 Y. Zhou, L. Hu and G. Grüner, “A method of printing carbon nanotube thin films”, Appl. Phys. Lett. 88, 123109 (2006)) for controlled deposition of large area highly conducting carbon nanotube films with high homogeneity on various substrates, including PET (polyethylene), glass, PMMA (polymethyl-methacrylate), and silicon. The films can also be printed in a patterned fashion for use as building blocks in electronic devices.

To prepare nanowire films, nanowires are dispersed in an aqueous solution. The solvent can be water, toluene and other organic and inorganic materials. Then the solution is bath-sonicated, typically for 16 hour at 100 W and centrifuged at 15000 rcf (relative centrifugal field). Alumina filters with a pore size of 0.1-0.2 μm (Whatman Inc.) are suitable to be used in the vacuum filtration. After the filtration, the filtered film is rinsed by deionized water for several minutes. Heat treatment is required to remove the PVP with a temperature between typically 150 and 250° C. for several minutes. The sheet resistance can be varied over a wide range by controlling the amount of nanowires used. For networks just above the percolation threshold, the sheet resistance reduces dramatically with the increase of nanotube amount, while in the region far from the threshold, the sheet resistance decreases inversely with the network density, or film thickness, as expected for constant conductivity.

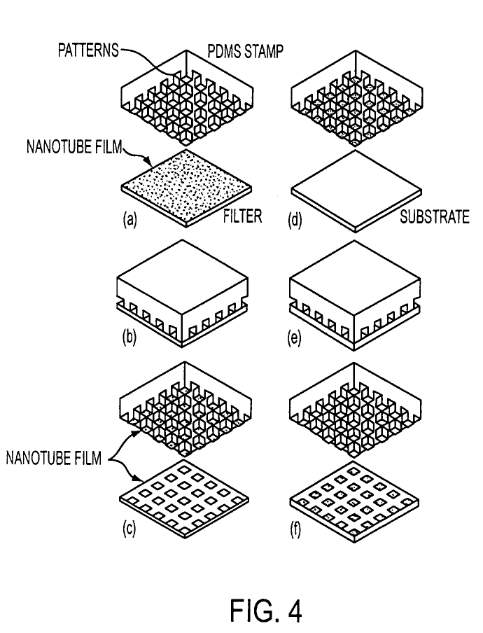

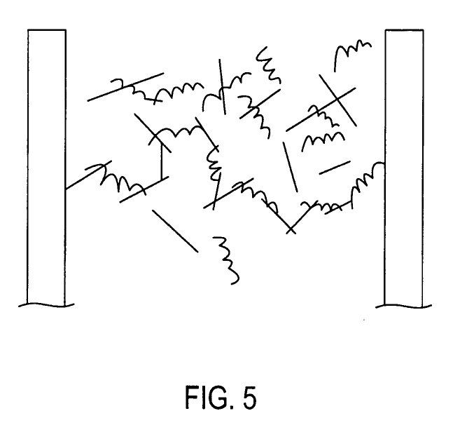

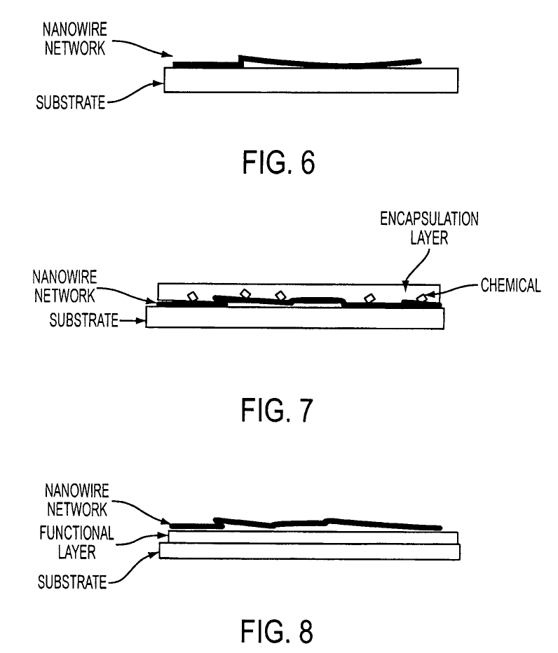

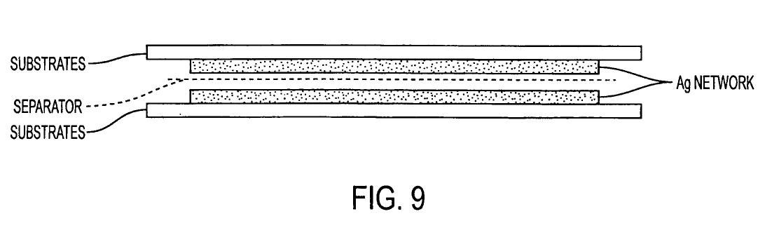

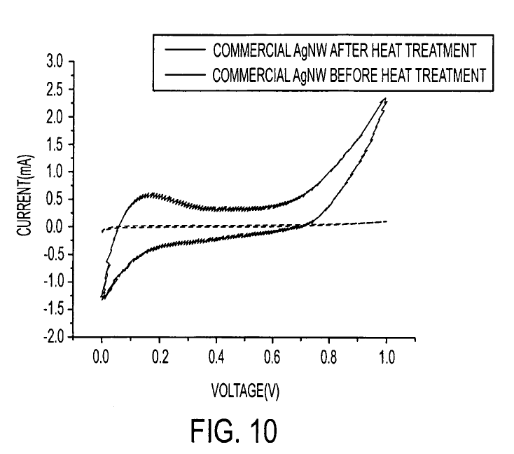

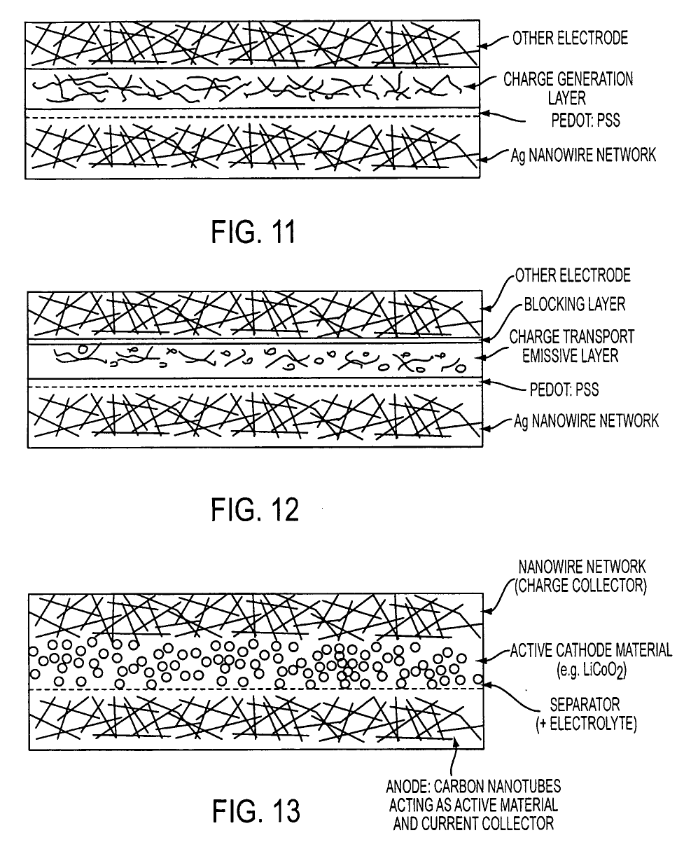

PDMS stamps for transfer printing can be fabricated by using SYLGARD® 184 silicone elastomer kit (Dow Corning Inc.) with silicon substrates as masters. To make patterned PDMS stamps, SU-8-25 resist (MicroChem. Inc.) can be spun onto silicon substrates and patterned by standard optical lithography. Silicon masters are pretreated with two hours of vacuum silanization in the vapor of (Tridecafluoro-1,1,2,2-tetrahydrooctyl)-1-trichlorosilane. Subsequently the silicone elastomer base and the curing agent are mixed together with a ratio of 10:1 in this example. After two hours of curing in the vacuum to remove the bubbles, the mixture is cast onto the silicon master, which is followed by one hour of vacuum curing and two hours of oven baking at 65° C. Finally, the PDMS stamp is removed from the silicon master. FIG. 4 illustrates a patterned PDMS stamp, together with the fabrication process.

To remove the nanowire films from the filters, one first makes conformal contact between the stamp and the films on the filter (FIG. 4(b)). As soon as the wetting due to the conformal contact is seen, the stamp is raised from the filter and the patterned films are transferred onto the stamp (FIG. 4(c)). Transfer of nanowire films from one surface to another surface is guided by surface energies of the two surfaces. Since the nanowire films loosely sit on the alumina filters, they can be fully transferred onto the PDMS surface even though PDMS has a low surface energy of 19.8 mJ/m². The same filter can be reused for fabrication of another film.

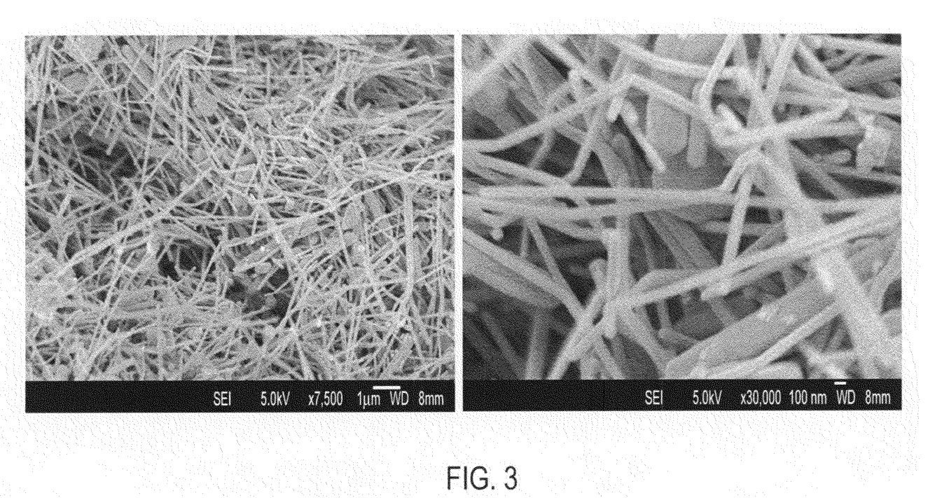

The availability of patterned nanowire films on PDMS stamps (FIG. 4(d)) readily allows them to be printed onto various flat substrates with a higher surface energy, such as PET (44.6 mJ/m²), glass (47 mJ/m²), and PMMA (41 mJ/m²). The surface energy of silicon substrates can be increased by oxygen plasma cleaning and vapor silanization using (aminopropyl)triethoxysilane. To start the transfer, one first contacts the PDMS stamp with nanowire films onto the receiving substrate (FIG. 4(e)). After a few minutes of mild heating at 80° C., substantially all nanowire films on the stamp are transferred onto the receiving substrate by simply removing the stamp from the substrate (FIG. 4(f)). The smallest pattern size that can be achieved by the printing method according to an embodiment of the invention is 20 μm, limited by the SU-8-25 resist based optical lithography to make the silicon master. Usage of PDMS stamps with smaller feature sizes may lead to patterns of nanowire films with higher resolution. FIG. 3(b) shows a photo image of a transparent and homogeneous film with a two-inch diameter on a flexible PET substrate. Recyclable use of filters and stamps may allow utilization of high cost, large area filters and PDMS stamps at the industrial scale without significantly increasing the fabrication cost of thin films.

### 4. Multiple Networks

Silver nanowire networks can also form part of a network with a multitude of nanoscale components.

Structures within the scope of the current invention include:

1) two or more interpenetrating nano-scale networks as an electronic material (having a finite electronic conduction) and the various methods that may be used to fabricate such networks. The networks can be free-standing or on a substrate. More particularly, some embodiments of the present invention are directed to a multitude of interpenetrating nano-structured networks that are suitable for use in electronic applications, such as resistors, diodes, transistors solar cells and sensors;

2) a three component structure: a (1) substrate and (2) functional layer together with a (3) network or networks of nano-structured materials; and a (1) substrate together with a (2) network or networks of nano-structured materials and an encapsulation layer (3);

3) a four component structure: a (1) network or networks together with a (2) functional material on a (3) substrate and an (4) encapsulation material that prevents the functional material to be removed from the network and substrate, and the various methods that may be used to fabricate such structures that are suitable for use in electronic applications, such as resistors, diodes, transistors solar cells and sensors;

4) combinations of the above.

1. Examples of the nano-scale materials that can form the two nano-structure networks with silver nanowires include

inorganic nanowires,

polymeric nanofibers,

carbon nanotubes,

organic fibers such as that from cloths,

metallic nano-particles,

biological materials, such as a protein or DNA,

nano-structured light sensitive materials, such as a PMPV,

nanoporous materials such as aerogels, carbon black and activated carbon.

2. The encapsulation agent can be a

polymer such as a parylene, a PEDOT:PSS, Poly(3,4ethylenedioxythiophene)poly(styrenesulphonate)

light sensitive material, such as a poly((m-phenylenevinyle)-co-)2,3.diotyloxy-p-phenylene)), PmPV.

5. Electronic Device with Ag Nanowire Components

Charge storage devices, batteries and capacitors drive a variety of electronic devices and have an increasing role due to portable consumer electronics. Charge storage devices based on nanostructured materials, together with the novel manufacturing route make such devices valuable for a range of applications where portable, light weight, disposable power is required. Such applications include smart cards, functional RFID devices, cheap disposable power sources for portable electronics and wearable electronics.

We have fabricated a charge storage device, a supercapacitor (SC), that incorporates a silver nanowire network, or film, as the charge collector and electrode according to an embodiment of the current invention. Cyclic voltammetry (CV) and galvanostatic charge/discharge experiments were used to determine the capacitance of the nanowire network electrode/charge collector. For all measurements, a computer controlled potentiostat (Jaissle IMP 83-PC, Jaissle Electronic GmbH, Waiblingen, German) was used. From the CV, we calculated the specific capacitance c of our device according to c=i/v, where v is the scan rate (20 mV/s) and i the corresponding current of the voltage applied. It was found that the specific capacitance of our device to be 0.8 F/g at 1 Volt.

The stability of the films was tested with respect to several electrolytes. Table 1 shows the change of the resistance of the films when subjected to the electrolytes. No substantial change is observed as an indication of the absence of significant chemical reaction between the silver nanowires and the electrolytes. Polymer electrolytes such as described in M. Kaemgen et al Appl. Phys. Lett 90, 264101 (2007) can be equally well applied.

The functional device demonstrates that random networks of nanowires can serve as charge transport supporting layers. Such devices can include solar cells, optical detectors, and batteries. Solar cells can be fabricated following the fabrication described in M. W. Rowell Appl. Phys. Lett. 88, 233506 (2006) and light emitting diodes following the fabrication procedure described in Nano Letter 6, 2472 (2006) in combination with the teachings herein. Batteries can be fabricated following the publication A. Kiebele and G. Gruner Appl. Phys Lett. 91, 144304 (2007) in combination with the teachings herein.

The embodiments illustrated and discussed in this specification are intended only to teach those skilled in the art the best way known to the inventors to make and use the invention. Nothing in this specification should be considered as limiting the scope of the present invention. The above-described embodiments of the invention may be modified or varied, and elements added or omitted, without departing from the invention, as appreciated by those skilled in the art in light of the above teachings. It is therefore to be understood that, within the scope of the claims and their equivalents, the invention may be practiced otherwise than as specifically described.

TABLE 1
Change of the electrical resistance of Ag nanowre
networks when subjected to various chemicals.

| | R before | R during |
|---|---|---|
| Electrolyte | (Ohms) | (Ohms) |
| NH4Cl | 76.7 | 62.1 |
| KOH | 76 | 67.2 |
| H3PO4 | 27.3 | 24.8 |
| H2O | 36.1 | 32.3 |

1-19. (canceled)

20. A transparent conductor comprising: a substrate; and a conductive layer on the substrate, the conductive layer including a plurality of metal nanowires.

21. The transparent conductor of claim 20 wherein the metal nanowires are silver nanowires.

22. The transparent conductor of claim 20 wherein each nanowire has an aspect ratio of about 100.

23. The transparent conductor of claim 20 wherein the conductive layer includes a matrix.

24. The transparent conductor of claim 23 wherein the transparent conductor is surface conductive.

25. The transparent conductor of claim 23 wherein the matrix is optically clear.

26. The transparent conductor of claim 24 where the matrix material is polyurethane, polyacrylic, silicone, polyacrylate, polysilane, polyester, polyvinyl chloride, polystyrene, polyolefin, fluoropolymer, polyamide, polyimide, polynorborene, acrylonitrile-butadiene-styrene copolymer, or copolymers or blends thereof.

27. The transparent conductor of claim 24 wherein the matrix material is an inorganic material.

28. The transparent conductor of claim 23 wherein each metal nanowire or a portion of the plurality of metal nanowires includes at least one section that protrudes above a surface of the matrix.

29. The transparent conductor of claim 23 wherein the conductive layer is patterned such that first regions of the surface of the transparent conductor are conductive and second regions of the surface of the transparent conductor are non-conductive.

30. The transparent conductor of claim 20 wherein the substrate is rigid.

31. The transparent conductor of claim 30 wherein the substrate is glass, polyacrylate, polyolefin, polyvinyl chloride, fluoropolymer, polyamide, polyimide, polysulfone, silicone, glass resin, polyetheretherketone, polynorborene, polyester, polyvinyls, acrylonitrile-butadiene-styrene copolymer, or polycarbonate or a copolymer or blend or laminate of these materials.

32. The transparent conductor of claim 20 wherein the substrate is flexible.

33. The transparent conductor of claim 32 wherein the substrate is polyacrylate, polyolefin, polyvinyl chloride, fluoropolymer, polyamide, polyimide, polysulfone, silicone, glass resin, polyetheretherketone, polynorborene, polyester, polyvinyls, acrylonitrile-butadiene-styrene copolymer, or polycarbonate or a copolymer or blend or laminate of these materials.

34. The transparent conductor of claim 20 further comprising one or more anti-reflective layers, anti-glare layers, adhesive layers, barriers, hard coat, or a protective film.

35. The transparent conductor of claim 34 comprising an anti-reflective layer positioned over the conductive layer, and an adhesive layer positioned between the conductive layer and the substrate.

36. The transparent conductor of claim 34 comprising a hard coat over the conductive layer, a barrier layer positioned between the conductive layer and the substrate, and an anti-reflective layer below the substrate.

37. The transparent conductor of claim 34 comprising an anti-reflective layer, anti-glare and a barrier layer positioned above the conductive layer, an adhesive layer positioned between the conductive layer and the substrate, and an anti-reflective layer below the substrate.

38. The transparent conductor of claim 20 further comprising one or more corrosion inhibitors.

39. The transparent conductor of claim 38 wherein the one or more corrosion inhibitors are housed in one or more reservoirs and can be released in vapor phase.

40. The transparent conductor of claim 38 wherein the corrosion inhibitor is benzotriazole, tolytriazole, butyl benzyl triazole, dithiothiadiazole, alkyl dithiothiadiazoles and alkylthiols, 2-aminopyrimidine, 5,6-dimethylbenzimidazole, 2-amino-5-mercapto-1,3,4-thiadiazole, 2-mercaptopyrimidine, 2-mercaptobenzoxazole, 2-mercaptobenzothiazole, or 2-mercaptobenzimidazole.

41. The transparent conductor of claim 39 wherein the corrosion inhibitor is benzotriazole, dithiothiadiazole or alkyl dithiothiadiazoles.

42. The transparent conductor of claim 38 wherein the corrosion inhibitor is an H₂S scavenger.

43. The transparent conductor of claim 42 wherein the corrosion inhibitor is acrolein, glyoxal, triazine, or n-chlorosuccinimide.

44. The transparent conductor of claim 20 having a light transmission of at least 50%.

45. The transparent conductor of claim 20 having a surface resistivity of no more than 1×10⁶Ω/□.

46. The transparent conductor of claim 20 wherein the metal nanowires form a conductive network including a plurality of nanowire crossing points, at least one of the nanowires at each of at least a portion of the plurality of nanowire crossing points having a flattened cross section.

47. A method of fabricating a transparent conductor comprising: depositing a plurality of metal nanowires on a surface of a substrate, the metal nanowires being dispersed in a liquid; and forming a metal nanowire network layer on the substrate by allowing the liquid to dry.

48. The method of claim 47 wherein the metal nanowires are silver nanowires.

49. The method of claim 47 wherein the liquid further comprises an additive selected from carboxy methyl cellulose, 2-hydroxy ethyl cellulose, hydroxy propyl methyl cellulose, methyl cellulose, poly vinyl alcohol, tripropylene glycol, and xanthan gum.

50. The method of claim 47 further comprising pre-treating the surface of the substrate prior to depositing the metal nanowires.

51. The method of claim 50 wherein pre-treating the surface of the substrate creates a pattern comprising at least one pre-treated region and at least one untreated region.

52. The method of claim 51 wherein the metal nanowire network layer is only formed on the pre-treated region.

53. The method of claim 50 wherein pre-treating the surface includes depositing an intermediate layer on the surface of the substrate, plasma treatment, UV-ozone treatment, or corona discharge.

54. The method of claim 47 further comprising post-treating the metal nanowire network layer.

55. The method of claim 54 comprising applying pressure, heat or combination thereof to the metal nanowire network layer.

56. The method of claim 54, wherein post-treating the metal nanowire network layer increases the conductivity thereof.

57. The method of claim 47 further comprising: depositing a matrix material on the metal nanowire network layer; and curing the matrix material to form a matrix, the matrix and the metal nanowires embedded therein forming a conductive layer.

58. The method of claim 47 further comprising: causing at least a section of each of a portion of the plurality of metal nanowires to protrude above a surface of the matrix to provide a conducting surface of the conductive layer.

59. The method of claim 47 wherein the matrix material comprises a polymer dispersed in a solvent.

60. The method of claim 47 wherein curing comprises evaporating the solvent.

61. The method of claim 47 wherein the matrix material comprises a prepolymer.

62. The method of claim 61 wherein the prepolymer is photo-curable.

63. The method of claim 61 wherein the prepolymer is thermal-curable.

64. The method of claim 57 wherein the matrix material is deposited according to a pattern, providing coated regions and uncoated regions of the metal nanowire network layer, the coated regions curing into a patterned matrix.

65. The method of claim 64 further comprising removing the metal nanowires in the uncoated regions.

66. The method of claim 64 wherein the matrix material is printed on the substrate according to the pattern.

67. The method of claim 57 wherein curing comprises selectively curing, according to a pattern, the matrix material to form cured regions and uncured regions.

68. The method of claim 67 further comprising removing the matrix material and the metal nanowires in the uncured regions.

69. The method of claim 67 wherein the cured regions form patterned conductive layers.

70. The method of claim 47 wherein the substrate is flexible.

71. The method of claim 70 wherein the substrate is driven by a rotating reel along a traveling path, and the metal nanowires are deposited at a first deposition station along the traveling path, and the matrix material is deposited at a second deposition station along the traveling path.

72. The method of claim 71 wherein the substrate is positioned on a conveyor belt.

73. The method of claim 71 further comprises curing the matrix material at a patterning station along the traveling path.

74. The method of claim 73 wherein curing comprises continuously exposing the matrix material to light irradiation.

75. The method of claim 74 wherein the light irradiation is projected to the matrix material according to a pattern.

76. The method of claim 73 wherein curing comprises heating the matrix material layer according to a pattern using a heat insulating mask.

77. The method of claim 73 wherein the matrix material is patterned into cured regions and uncured regions.

78. The method of claim 77 further comprising removing the matrix material and the metal nanowires in the uncured region.

79. The method of claim 47 wherein the substrate is a flexible donor substrate.

80. The method of claim 79 wherein the flexible donor substrate is coated with a release layer.

81. The method of claim 79 further comprising detaching the conductive layer from the flexible donor substrate and applying the conductive layer to a substrate of choice.

82. The method of claim 81 wherein the conductive layer is patterned prior to being detached from the flexible donor substrate.

83. The method of claim 81 wherein the substrate of choice comprises at least one heated region and at least one unheated region, wherein the conductive layer bonds the heated region more firmly than it bonds with the unheated region.

84. The method of claim 83 further comprising removing only the conductive layer in the unheated region.

85. The method of claim 81 wherein the conductive layer is applied to the substrate of choice by applying pressure to the conductive layer according to a pattern, and wherein the conductive layer bonds more firmly with a pressured region than it with an unpressured region.

86. The method of claim 85 further comprising removing only the conductive layer on the unpressured region.

87. The method of claim 81 wherein the substrate of choice is rigid.

88. The method of claim 81 wherein the substrate of choice is flexible.

89. A laminated structure comprising: a flexible donor substrate; and a conductive layer including a matrix embedded with a plurality of metal nanowires.

90. The laminated structure of claim 89 further comprising a release layer positioned between the flexible donor substrate and the conductive layer, the release layer being detachable from the conductive layer.

91. The laminated structure of claim 89 further comprising an adhesive layer positioned on the conductive layer.

92. The laminated structure of claim 89 further comprising an overcoat layer positioned between the flexible donor substrate and the conductive layer, the overcoat being in contact with the conductive layer.

93. The laminated structure of claim 92 wherein the overcoat is a hard coat, a protective film, an anti-reflective layer, a anti-glare layer, a barrier layer, or a combination thereof.

94. A display device comprising at least one transparent electrode having a conductive layer, the conductive layer including a plurality of metal nanowires.

95. The display device of claim 94 wherein the conductive layer further comprises a matrix, the metal nanowires being embedded in the matrix.

96. The display device of claim 94 wherein the metal nanowires are silver nanowires.

97. The display device of claim 95 wherein the matrix is an optically clear polymer.

98. The display device of claim 95 wherein the transparent electrode further comprises a corrosion inhibitor.

99. The display device of claim 98 wherein the corrosion inhibitor is benzotriazole, tolytriazole, butyl benzyl triazole, dithiothiadiazole, alkyl dithiothiadiazoles and alkylthiols, 2-aminopyrimidine, 5,6-dimethylbenzimidazole, 2-amino-5-mercapto-1,3,4-thiadiazole, 2-mercaptopyrimidine, 2-mercaptobenzoxazole, 2-mercaptobenzothiazole, or 2-mercaptobenzimidazole.

100. The display device of claim 98 wherein the corrosion inhibitor is acrolein, glyoxal, triazine, or n-chlorosuccinimide.

101. The display device of claim 94 wherein the display device is a touch screen, a liquid crystal display, or a flat panel display.

102. The transparent conductor of claim 20 wherein a surface loading level of the metal nanowires on the substrate is about 0.05 μg/cm² to about 10 g/cm².

103. A composition comprising: a solvent; a viscosity modifier; a surfactant; and a plurality of metal nanowires wherein the percentage by weight of nanowires is from 0.05% to 1.4%.

104. The composition of claim 103 wherein the solvent is water, an alcohol, a ketone, an ether, an hydrocarbon or an aromatic solvent.

105. The composition of claim 103 wherein the viscosity modifier is hydroxypropyl methyl cellulose (HPMC), methyl cellulose, xanthan gum, polyvinyl alcohol, carboxy methyl cellulose, or hydroxylethyl cellulose.

106. The composition of claim 103 wherein the surfactant is Zonyl® FSN, Zonyl® FSO, Zonyl® FSH, Triton, Dynol, n-Dodecyl-β-D-maltoside, or Novek®.

107. The transparent conductor of claim 23 wherein the matrix includes a prepolymer.

108. The transparent conductor of claim 107 wherein the prepolymer is photo-curable.

109. The transparent conductor of claim 23 wherein the matrix includes a corrosion inhibitor.

110. The transparent conductor of claim 23 wherein the matrix includes: an acrylate monomer; a multifunctional acrylate monomer; and at least one photoinitiator.

111. The transparent conductor of claim 110 wherein the matrix includes: 2-ethylhexyl acrylate; trimethylolpropane triacrylate (TMPTA); an adhesion promoter; and a photoinitiator.
